(19) United States
(12) Patent Application Publication
(10) Pub. No.: US 2026/0005011 A1
(43) Pub. Date: Jan. 1, 2026

(54) SUBSTRATE PROCESSING METHOD

(71) Applicant: SCREEN Holdings Co., Ltd., Kyoto (JP)

(72) Inventors: Kota TANIKAWA, Kyoto-shi (JP); Manabu TAKUSARI, Kyoto-shi (JP); Hiroyuki YASHIKI, Kyoto-shi (JP)

(21) Appl. No.: 19/235,452

(22) Filed: Jun. 11, 2025

(30) Foreign Application Priority Data
Jun. 26, 2024 (JP) 2024-102968

(51) Int. Cl. H01L 21/02; B08B 3/04; B08B 3/08; H01L 21/67

(52) U.S. Cl. CPC H01L 21/02057; B08B 3/041; B08B 3/08; H01L 21/67051

(57) ABSTRACT

A substrate processing method includes: holding a substrate having a first main surface and a second main surface; rotating the substrate and supplying a hydrofluoric acid-containing liquid to the second main surface of the substrate, the hydrofluoric acid-containing liquid containing hydrofluoric acid; after supplying the hydrofluoric acid-containing liquid to the second main surface of the substrate, rotating the substrate and supplying a rinse liquid to the second main surface of the substrate; and after supplying the rinse liquid to the second main surface of the substrate, rotating the substrate and supplying a hydrophobizing liquid to the first main surface of the substrate.

### BACKGROUND

### Technical Field

The present disclosure relates to a substrate processing method.

### Description of the Background Art

A substrate processing apparatus of single-substrate type that processes a substrate has been disclosed (see Japanese Patent Application Laid-Open No. 2022-27088). In Japanese Patent Application Laid-Open No. 2022-27088, the substrate processing apparatus makes a front surface of a substrate hydrophobic with a hydrophobizing liquid, washes away the hydrophobizing liquid on the substrate with a rinse liquid, and then dries the substrate. Collapse of a pattern of the substrate during drying is thereby suppressed.

### SUMMARY

In one aspect, a substrate processing method includes: holding a substrate having a first main surface and a second main surface; rotating the substrate and supplying a hydrofluoric acid-containing liquid to the second main surface of the substrate, the hydrofluoric acid-containing liquid containing hydrofluoric acid; after supplying the hydrofluoric acid-containing liquid to the second main surface of the substrate, rotating the substrate and supplying a rinse liquid to the second main surface of the substrate; and after supplying the rinse liquid to the second main surface of the substrate, rotating the substrate and supplying a hydrophobizing liquid to the first main surface of the substrate.

In another aspect, a substrate processing method includes: holding a substrate having a first main surface and a second main surface; rotating the substrate and supplying a removal liquid to the second main surface of the substrate, the removal liquid removing an oxide; after supplying the removal liquid to the second main surface of the substrate, rotating the substrate and supplying a rinse liquid to the second main surface of the substrate; and after supplying the rinse liquid to the second main surface of the substrate, rotating the substrate and supplying a hydrophobizing liquid to the first main surface of the substrate.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically showing one example of a configuration of a substrate processing apparatus;

FIG. 2 is a block diagram schematically showing one example of an internal configuration of a controller;

FIG. 3 is a diagram schematically showing one example of a configuration of a processing unit according to a first embodiment;

FIG. 4 is a flowchart showing one example of operation of the processing unit;

FIGS. 5A and 5B are diagrams schematically showing examples of states of the processing unit in respective steps;

FIGS. 6A and 6B are diagrams schematically showing examples of states of the processing unit in respective steps;

FIGS. 7A and 7B are diagrams schematically showing examples of states of the processing unit in respective steps;

FIGS. 8A and 8B are diagrams schematically showing examples of states of the processing unit in respective steps; and

FIG. 9 is a diagram schematically showing one example of a configuration of a processing unit according to a second embodiment.

### DESCRIPTION OF THE PREFERRED EMBODIMENTS

When a hydrophobizing liquid is supplied to a front surface of a substrate, a portion of the hydrophobizing liquid wraps around an end surface of the substrate and acts on a peripheral edge portion of a back surface of the substrate. The peripheral edge portion of the back surface of the substrate is thus also made hydrophobic. Hydrophobizing is implemented by substituting a substituent group on the front surface of the substrate with a hydrophobic group (organic matter). That is to say, the organic matter is present in the peripheral edge portion of the back surface of the processed substrate. The peripheral edge portion of the back surface of the processed substrate is brought into contact with a hand of a transport robot, so that the organic matter in the peripheral edge portion of the back surface might adhere to the hand. That is to say, the hand might be contaminated. If the contaminated hand lifts another substrate, the other substrate might be contaminated.

It is thus an object of the present disclosure to provide a substrate processing method that can reduce a possibility of contamination of a substrate with organic matter.

Embodiments will be described in detail below with reference to the accompanying drawings. In the drawings, dimensions and the number of components are exaggerated or simplified as necessary for ease of understanding. Parts having similar configurations and functions bear the same reference signs, and description is not repeated below.

In description made below, similar components bear the same reference signs and have similar names and functions. Detailed description thereof is thus sometimes omitted to avoid redundancy.

Even when ordinal numbers, such as “first” and “second”, are used in description made below, these terms are used for the sake of convenience for ease of understanding of the embodiments, and an order is not limited to an order that can be represented by the ordinal numbers.

When an expression indicating a relative or an absolute positional relationship (e.g., “in one direction”, “along one direction”, “parallel”, “orthogonal”, “central”, “concentric”, and “coaxial”) is used, the expression not only exactly represents the positional relationship but also represents a state in which an angle or a distance is relatively changed within tolerance or to the extent that a similar function can be obtained unless otherwise noted. When an expression indicating equality (e.g., “same”, “equal”, and “homogeneous”) is used, the expression not only represents quantitatively exact equality but also represents a state in which there is a difference within tolerance or to the extent that a similar function can be obtained unless otherwise noted. When an expression indicating a shape (e.g., a “quadrangular shape” and a “cylindrical shape”) is used, the expression not only geometrically exactly represents the shape but also represents a shape having irregularities, a chamfer, and the like to the extent that a similar effect can be obtained unless otherwise noted. When an expression “comprising”, “being provided with”, “being equipped with”, “including”, or “having” one component is used, the expression is not an exclusive expression excluding the presence of the other components. When an expression “at least one of A, B, and C” is used, the expression includes only A, only B, only C, any two of A, B, and C, and all of A, B, and C.

### First Embodiment

### <Overall Configuration of Substrate Processing Apparatus>

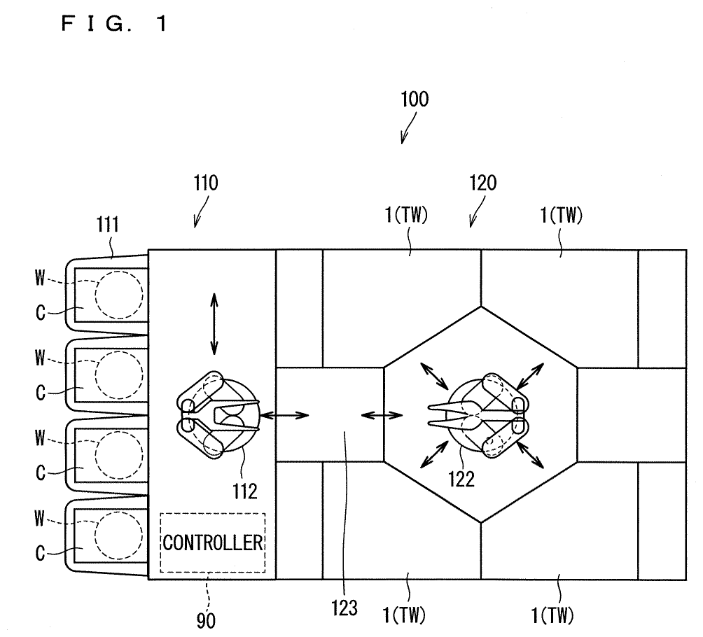

FIG. 1 is a plan view schematically showing one example of a configuration of a substrate processing apparatus 100. The substrate processing apparatus 100 is a processing apparatus of single-substrate type that processes one substrate W at a time.

Examples of the substrate W include a semiconductor wafer, a substrate for liquid crystal display, a substrate for organic electroluminescence (EL), a substrate for flat panel display (FPD), a substrate for optical display, a substrate for magnetic disk, a substrate for optical disc, a substrate for magnetooptical disc, a substrate for photomask, and a substrate for solar cell. The substrate W has a thin planar shape. Opposite main surfaces of the substrate W are hereinafter referred to as a first main surface Wa and a second main surface Wb. The second main surface Wb is a surface opposite the first main surface Wa. Assume that the substrate W is a semiconductor wafer below. The substrate W may be a silicon semiconductor, for example. The substrate W has a disc shape, for example. The substrate W has a diameter of approximately 300 mm, for example, and has a thickness of approximately 0.5 mm or more and 3 mm or less, for example. A pattern has been formed in the first main surface Wa of the substrate W. The pattern herein includes a semiconductor pattern, for example.

In the example of FIG. 1, the substrate processing apparatus 100 includes an indexer block 110, a processing block 120, and a controller 90. The processing block 120 is a part that mainly processes the substrate W, and the indexer block 110 is a part that mainly transports the substrate W between an exterior of the substrate processing apparatus 100 and the processing block 120.

The indexer block 110 includes load ports 111 and a first transport 112. Externally transported substrate containers (hereinafter referred to as carriers) C are mounted to the load ports 111. Each of the carriers C contains therein a plurality of substrates W arranged to be spaced apart from one another in a vertical direction, for example. In the example of FIG. 1, the plurality of load ports 111 are arranged.

The first transport 112 is a transport robot and can take an unprocessed substrate W out of the carrier C mounted to each of the load ports 111. The first transport 112 can also be referred to as an indexer robot. The first transport 112 transports the unprocessed substrate W taken out of the carrier C to the processing block 120. The processing block 120 can process the unprocessed substrate W. The first transport 112 can also receive a processed substrate W from the processing block 120 and transport the processed substrate W to the carrier C mounted to each of the load ports 111.

In the example of FIG. 1, the processing block 120 includes a plurality of processing units 1 and a second transport 122. The second transport 122 is a transport robot and can transport the substrate W between the first transport 112 and the plurality of processing units 1. In the example of FIG. 1, the processing block 120 also includes a mount 123. The mount 123 is a shelf to which a plurality of substrates W can be mounted while being arranged in the vertical direction, for example. The first transport 112 mounts the unprocessed substrate W to the mount 123. The second transport 122 takes the unprocessed substrate W out of the mount 123 and transports the substrate W to one of the processing units 1. The processing unit 1 processes the substrate W. A configuration of the processing unit 1 will be described below. The second transport 122 takes the processed substrate W out of the processing unit 1 and transports the substrate W to the mount 123. The first transport 112 takes the substrate W out of the mount 123 and transports the substrate W to the carrier C mounted to each of the load ports 111.

In the example of FIG. 1, the plurality of (e.g., four) processing units 1 are provided to surround the second transport 122 in plan view. The second transport 122 can also be referred to as a center robot. At each position in plan view, the plurality of processing units 1 may be stacked in the vertical direction. That is to say, a plurality of (four in the figure) towers TW each including the plurality of processing units 1 stacked in the vertical direction may be provided to surround the second transport 122.

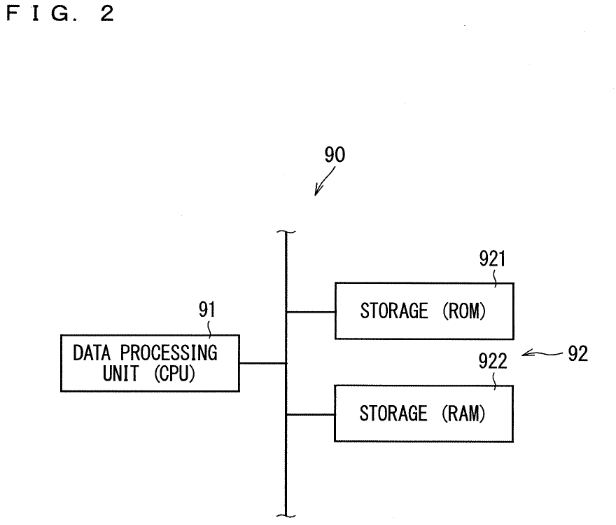

The controller 90 performs overall control of the substrate processing apparatus 100. Specifically, the controller 90 controls the first transport 112, the second transport 122, and the processing units 1. FIG. 2 is a block diagram schematically showing one example of an internal configuration of the controller 90. The controller 90 is an electronic circuit and includes a data processing unit 91 and a storage 92, for example. In a specific example of FIG. 2, the data processing unit 91 and the storage 92 are connected to each other via a bus 93. The data processing unit 91 may be an arithmetic processing apparatus, such as a central processor unit (CPU). The storage 92 may include a non-transitory storage (e.g., read only memory (ROM)) 921 and a transitory storage (e.g., random access memory (RAM)) 922. The non-transitory storage 921 may store therein a program that defines processing performed by the controller 90, for example. The data processing unit 91 executes the program, so that the controller 90 can perform processing defined by the program. Part or all of processing performed by the controller 90 may naturally be performed by hardware, such as a dedicated logic circuit.

### <Overview of Processing Unit>

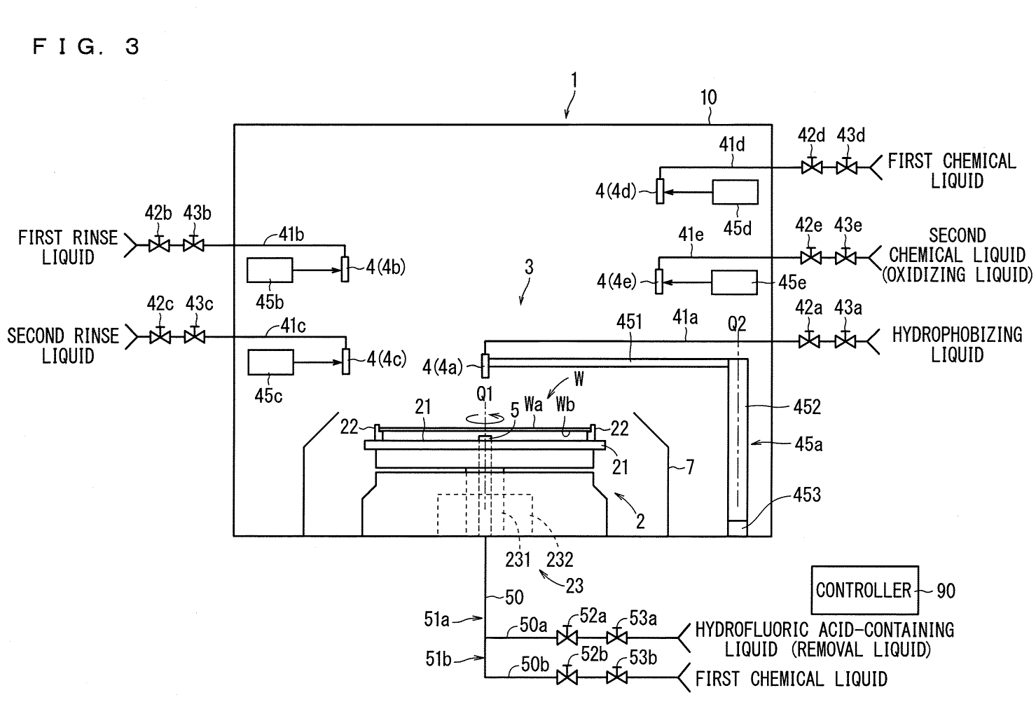

FIG. 3 is a diagram schematically showing one example of a configuration of a processing unit 1 according to a first embodiment. Not all the processing units 1 belonging to the substrate processing apparatus 100 are required to have the configuration illustrated in FIG. 3. At least one of the processing units 1 of the substrate processing apparatus 100 is only required to have the configuration illustrated in FIG. 3.

The processing unit 1 includes a substrate holder 2 and a discharger 3.

In the example of FIG. 3, the processing unit 1 also includes a chamber 10. The chamber 10 has a box shape and has an internal space corresponding to a processing space for processing the substrate W. The chamber 10 has an openable transport port (not illustrated). The second transport 122 transports the unprocessed substrate W into the chamber 10 through the transport port and transports the processed substrate W out of the chamber 10 through the transport port.

The substrate holder 2 is provided in the chamber 10 and rotates the substrate W around a rotation axis Q1 while holding the substrate W in a horizontal orientation. The horizontal orientation is herein an orientation in which a direction of a thickness of the substrate W extends along the vertical direction. The rotation axis Q1 is an axis passing through the center of the substrate W and extending along the vertical direction. The substrate holder 2 as described above can be referred to as a spin chuck.

The first main surface Wa of the substrate W in which the pattern has been formed herein faces vertically upwards. That is to say, in the example of FIG. 3, the first main surface Wa and the second main surface Wb of the substrate W held by the substrate holder 2 respectively correspond to an upper surface and a lower surface.

In the example of FIG. 3, the substrate holder 2 includes a spin base 21, chuck pins 22, and a rotation driver 23. The spin base 21 has a planar shape (e.g., a disc shape) and is provided in an orientation in which a direction of a thickness thereof extends along the vertical direction. The chuck pins 22 are provided on an upper surface of the spin base 21. The chuck pins 22 are provided at regular intervals circumferentially around the rotation axis Q1. The chuck pins 22 are each provided to be displaceable between a holding position and a releasing position described below. The holding position is a position at which each of the chuck pins 22 is in contact with a peripheral edge of the substrate W. Each of the chuck pins 22 is stopped at the holding position so that the chuck pins 22 hold the substrate W. FIG. 3 illustrates the chuck pins 22 each stopped at the holding position. The releasing position is a position at which each of the chuck pins 22 is away from the substrate W. Each of the chuck pins 22 is stopped at the releasing position so that holding of the substrate W by the chuck pins 22 is released. The substrate holder 2 includes a pin driver (not illustrated) that displaces the chuck pins 22. The pin driver includes a drive source, such as a motor and an air cylinder, and is controlled by the controller 90.

The rotation driver 23 includes a shaft 231 and a motor 232. An upper end of the shaft 231 is connected to a lower surface of the spin base 21, and the shaft 231 extends from the lower surface of the spin base 21 along the rotation axis Q1. The motor 232 is controlled by the controller 90 and rotates the shaft 231 around the rotation axis Q1. The spin base 21, the chuck pins 22, and the substrate W are thereby integrally rotated around the rotation axis Q1.

The substrate holder 2 may not necessarily include the chuck pins 22. The substrate holder 2 may hold the substrate W by chucking, such as vacuum chucking, electrostatic chucking, and Bernoulli chucking.

The discharger 3 discharges a processing liquid toward each of the first main surface Wa and the second main surface Wb of the substrate W held by the substrate holder 2. The discharger 3 can discharge a hydrophobizing liquid as one example of the processing liquid to the first main surface Wa of the substrate W. The discharger 3 can also discharge a hydrofluoric acid-containing liquid as one example of the processing liquid to the second main surface Wb of the substrate W.

In the example of FIG. 3, the discharger 3 includes at least one upper surface nozzle 4 and at least one lower surface nozzle 5. The upper surface nozzle 4 and the lower surface nozzle 5 are each a straight nozzle that discharges the processing liquid in a columnar shape, for example.

In the example of FIG. 3, the discharger 3 includes a hydrophobizing nozzle 4a as one example of the upper surface nozzle 4. The hydrophobizing nozzle 4a is provided above the substrate W held by the substrate holder 2 in the chamber 10. The hydrophobizing nozzle 4a discharges the hydrophobizing liquid toward the first main surface Wa of the substrate W. The hydrophobizing liquid is a liquid that makes a surface of the substrate W hydrophobic. The hydrophobizing liquid is a silylating liquid containing a silylating agent (also referred to as a silane coupling agent) in a liquid form, for example. The silylating agent includes hexamethyldisilazane (HMDS), for example. The hydrophobizing liquid is a liquid that substitutes a substituent group present on the first main surface Wa of the substrate W with a hydrophobic group. The substituent group is a hydroxy group (OH group), for example. The hydroxy group is a hydrophilic group. The hydrophobic group is an organic hydrophobic group contained in a molecule of the hydrophobizing liquid and is a trimethylsilyl group, for example. In this case, a hydrogen molecule of the hydroxy group present on the surface of the substrate W is substituted with the trimethylsilyl group to make the surface of the substrate W hydrophobic.

In the example of FIG. 3, the discharger 3 includes a supply tube 41a, a supply valve 42a, and a flow rate regulation valve 43a. A downstream end of the supply tube 41a is connected to the hydrophobizing nozzle 4a, and an upstream end of the supply tube 41a is connected to a hydrophobizing liquid supply source. The hydrophobizing liquid supply source includes a tank for storing the hydrophobizing liquid, for example. The supply valve 42a and the flow rate regulation valve 43a are inserted along the supply tube 41a. The supply valve 42a switches between opening and closing of the supply tube 41a, and the flow rate regulation valve 43a regulates a flow rate of the hydrophobizing liquid flowing along the supply tube 41a. The supply valve 42a and the flow rate regulation valve 43a are controlled by the controller 90.

In the example of FIG. 3, the hydrophobizing nozzle 4a is provided to be movable by a movement driver 45a. The movement driver 45a moves the hydrophobizing nozzle 4a between a processing position and a standby position described below. The processing position is a position at which the hydrophobizing nozzle 4a discharges the hydrophobizing liquid and is a position at which the hydrophobizing nozzle 4a faces a central portion of the substrate W in the vertical direction, for example. In the example of FIG. 3, the hydrophobizing nozzle 4a stopped at the processing position is illustrated. The standby position is a position at which the hydrophobizing nozzle 4a does not discharge the hydrophobizing liquid and is a position radially outside the substrate W, for example.

FIG. 3 illustrates one example of a specific configuration of the movement driver 45a. In the example of FIG. 3, the movement driver 45a includes an arm 451, a support column 452, and a drive source 453. The support column 452 is provided radially outside a guard 7, which will be described below, and extends along the vertical direction. The arm 451 extends horizontally and has a distal end connected to the hydrophobizing nozzle 4a and a proximal end connected to the support column 452. The drive source 453 is controlled by the controller 90 and reciprocally rotates the support column 452 around a central axis Q2 in a predetermined angular range. The drive source 453 includes a motor, for example. When the support column 452 is reciprocally rotated around the central axis Q2 in the predetermined angular range, the hydrophobizing nozzle 4a reciprocates circumferentially around the central axis Q2. The support column 452 is provided so that the processing position and the standby position are located on a movement trajectory of the hydrophobizing nozzle 4a. The movement driver 45a may not necessarily have the aspect of FIG. 3 and may include a direct-acting mechanism, such as a linear motor.

When the hydrophobizing nozzle 4a discharges the hydrophobizing liquid to the first main surface Wa of the substrate W during rotation of the substrate W, the hydrophobizing liquid sits on a central portion of the first main surface Wa of the substrate W, flows radially outwards with rotation of the substrate W, and splashes outwards from the peripheral edge of the substrate W. The hydrophobizing liquid acts on the first main surface Wa of the substrate W to make the first main surface Wa of the substrate W hydrophobic.

The lower surface nozzle 5 is provided below the substrate W held by the substrate holder 2 in the chamber 10. The lower surface nozzle 5 discharges the hydrofluoric acid-containing liquid toward the second main surface Wb of the substrate W. The hydrofluoric acid-containing liquid is a liquid containing hydrofluoric acid and is dilute hydrofluoric acid, for example. In the example of FIG. 3, the lower surface nozzle 5 is provided at a position at which the lower surface nozzle 5 faces the central portion of the substrate W in the vertical direction. As illustrated in FIG. 3, the lower surface nozzle 5 may protrude from a central portion of the spin base 21 of the substrate holder 2 toward the second main surface Wb of the substrate W.

In the example of FIG. 3, the discharger 3 includes a supply tube 51a, a supply valve 52a, and a flow rate regulation valve 53a. A downstream end of the supply tube 51a is connected to the lower surface nozzle 5, and an upstream end of the supply tube 51a is connected to a hydrofluoric acid-containing liquid supply source. In the example of FIG. 3, the spin base 21 of the substrate holder 2 has a through hole in the central portion thereof, and the shaft 231 is a hollow shaft. A portion of the supply tube 51a extends through the through hole of the spin base 21 and a hollow portion of the shaft 231 along the vertical direction. The hydrofluoric acid-containing liquid supply source includes a tank for storing the hydrofluoric acid-containing liquid, for example. The supply valve 52a and the flow rate regulation valve 53a are inserted along the supply tube 51a. The supply valve 52a switches between opening and closing of the supply tube 51a, and the flow rate regulation valve 53a regulates a flow rate of the hydrofluoric acid-containing liquid flowing along the supply tube 51a. The supply valve 52a and the flow rate regulation valve 53a are controlled by the controller 90.

In the example of FIG. 3, the discharger 3 can discharge a processing liquid different from the hydrophobizing liquid and the hydrofluoric acid-containing liquid toward the substrate W. Specifically, the discharger 3 includes a first rinse nozzle 4b, a second rinse nozzle 4c, a first chemical liquid nozzle 4d, and a second chemical liquid nozzle 4e as examples of the upper surface nozzle 4.

The first chemical liquid nozzle 4d is provided above the substrate W held by the substrate holder 2 in the chamber 10. In the example of FIG. 3, the first chemical liquid nozzle 4d is provided to be movable by a movement driver 45d. The movement driver 45d moves the first chemical liquid nozzle 4d between a processing position and a standby position. The processing position is a position at which the first chemical liquid nozzle 4d discharges a first chemical liquid and is a position at which the first chemical liquid nozzle 4d faces the central portion of the substrate W in the vertical direction, for example. The same applies to the processing position for each of the other upper surface nozzles 4. The standby position is a position at which the first chemical liquid nozzle 4d does not discharge the first chemical liquid and is a position radially outside the substrate holder 2, for example. The same applies to the standby position for each of the other upper surface nozzles 4. The movement driver 45d has a similar configuration to the movement driver 45a, for example. The first chemical liquid nozzle 4d discharges the first chemical liquid toward the first main surface Wa of the substrate W at the processing position. The first chemical liquid is a liquid to clean the substrate W, for example, and is a liquid that removes a native oxide film as one specific example. More specifically, the first chemical liquid includes hydrofluoric acid. The first chemical liquid may be dilute hydrofluoric acid. The native oxide film on the first main surface Wa of the substrate W can be removed with the first chemical liquid.

The second chemical liquid nozzle 4e is provided above the substrate W held by the substrate holder 2 in the chamber 10. In the example of FIG. 3, the second chemical liquid nozzle 4e is provided to be movable by a movement driver 45e. The movement driver 45e moves the second chemical liquid nozzle 4e between a processing position and a standby position. The movement driver 45e has a similar configuration to the movement driver 45a, for example.

The second chemical liquid nozzle 4e discharges a second chemical liquid toward the first main surface Wa of the substrate W at the processing position. The second chemical liquid is a liquid to form an oxide on the substrate W, for example. The second chemical liquid is a mixture of ammonium hydroxide, hydrogen peroxide, and water (i.e., SC1), for example. When the second chemical liquid is SC1, impurities, such as particles, on the first main surface Wa of the substrate W can be removed.

The first rinse nozzle 4b is provided above the substrate W held by the substrate holder 2 in the chamber 10. In the example of FIG. 3, the first rinse nozzle 4b is provided to be movable by a movement driver 45b. The movement driver 45b moves the first rinse nozzle 4b between a processing position and a standby position. The movement driver 45b has a similar configuration to the movement driver 45a, for example.

The first rinse nozzle 4b discharges a first rinse liquid toward the first main surface Wa of the substrate W at the processing position. The first rinse liquid is pure water (i.e., deionized water), for example. For example, after discharging the first chemical liquid from the first chemical liquid nozzle 4d toward the substrate W, the discharger 3 discharges the first rinse liquid from the first rinse nozzle 4b toward the substrate W. The first chemical liquid on the first main surface Wa of the substrate W can thereby be washed away with the first rinse liquid. That is to say, the first chemical liquid as the processing liquid on the first main surface Wa of the substrate W can be substituted with the first rinse liquid. Also after supply of the second chemical liquid to the substrate W, the first rinse nozzle 4b discharges the first rinse liquid toward the first main surface Wa of the substrate W. The second chemical liquid as the processing liquid on the first main surface Wa of the substrate W can thereby be substituted with the first rinse liquid.

The second rinse nozzle 4c is provided above the substrate W held by the substrate holder 2 in the chamber 10. In the example of FIG. 3, the second rinse nozzle 4c is provided to be movable by a movement driver 45c. The movement driver 45c moves the second rinse nozzle 4c between a processing position and a standby position. The movement driver 45c has a similar configuration to the movement driver 45a, for example.

The second rinse nozzle 4c discharges a second rinse liquid toward the first main surface Wa of the substrate W at the processing position. The second rinse liquid is an organic solvent, for example. The second rinse liquid may have higher volatility than the first rinse liquid. The second rinse liquid may have lower surface tension than the first rinse liquid. The organic solvent is isopropyl alcohol, for example. For example, after discharging the first rinse liquid from the first rinse nozzle 4b toward the substrate W, the discharger 3 discharges the second rinse liquid from the second rinse nozzle 4c toward the substrate W. The first rinse liquid as the processing liquid on the first main surface Wa of the substrate W can thereby be substituted with the second rinse liquid.

In the example of FIG. 3, the discharger 3 includes a supply tube 41b, a supply valve 42b, and a flow rate regulation valve 43b for the first rinse nozzle 4b, a supply tube 41c, a supply valve 42c, and a flow rate regulation valve 43c for the second rinse nozzle 4c, a supply tube 41d, a supply valve 42d, and a flow rate regulation valve 43d for the first chemical liquid nozzle 4d, and a supply tube 41e, a supply valve 42e, and a flow rate regulation valve 43e for the second chemical liquid nozzle 4e. A positional relationship among them is similar to the positional relationship among the hydrophobizing nozzle 4a, the supply tube 41a, the supply valve 42a, and the flow rate regulation valve 43a.

While the movement driver is provided for each of the upper surface nozzles 4 in the above-mentioned example, a movement driver that moves the plurality of upper surface nozzles 4 may be provided. Furthermore, while the upper surface nozzles 4 are provided for the respective processing liquids in the above-mentioned example, a single upper surface nozzle 4 may be provided for the plurality of processing liquids.

In the example of FIG. 3, the lower surface nozzle 5 of the discharger 3 can discharge the first rinse liquid. In the example of FIG. 3, the supply tube 51a includes a common tube 50, a first branch tube 50a, and a second branch tube 50b. A portion of the common tube 50 extends through the through hole of the spin base 21 and the hollow portion of the shaft 231 along the vertical direction. A downstream end of the common tube 50 is connected to the lower surface nozzle 5. A downstream end of the first branch tube 50a and a downstream end of the second branch tube 50b are connected to an upstream end of the common tube 50. An upstream end of the first branch tube 50a is connected to a hydrofluoric acid-containing liquid supply source, and an upstream end of the second branch tube 50b is connected to a first rinse liquid supply source. The common tube 50 and the first branch tube 50a constitute the supply tube 51a, and the common tube 50 and the second branch tube 50b constitute a supply tube 51b. The supply tube 51b connects the lower surface nozzle 5 and the first rinse liquid supply source.

The supply valve 52a and the flow rate regulation valve 53a are inserted along the first branch tube 50a. A supply valve 52b and a flow rate regulation valve 53b are inserted along the second branch tube 50b. The supply valve 52b switches between opening and closing of the supply tube 51b, and the flow rate regulation valve 53b regulates a flow rate of the first rinse liquid flowing along the supply tube 51b. The supply valve 52b and the flow rate regulation valve 53b are controlled by the controller 90.

In the example of FIG. 3, the processing unit 1 includes the guard 7. The guard 7 is tubular around the rotation axis Q1 and surrounds the substrate holder 2. The guard 7 can catch various processing liquids splashing from the peripheral edge of the substrate W. The processing liquid flows downwards along an inner peripheral surface of the guard 7. The processing liquid is drained outside the chamber 10 through an unillustrated drain tube provided in a lower portion of the guard 7.

### <Example of Operation of Substrate Processing Apparatus>

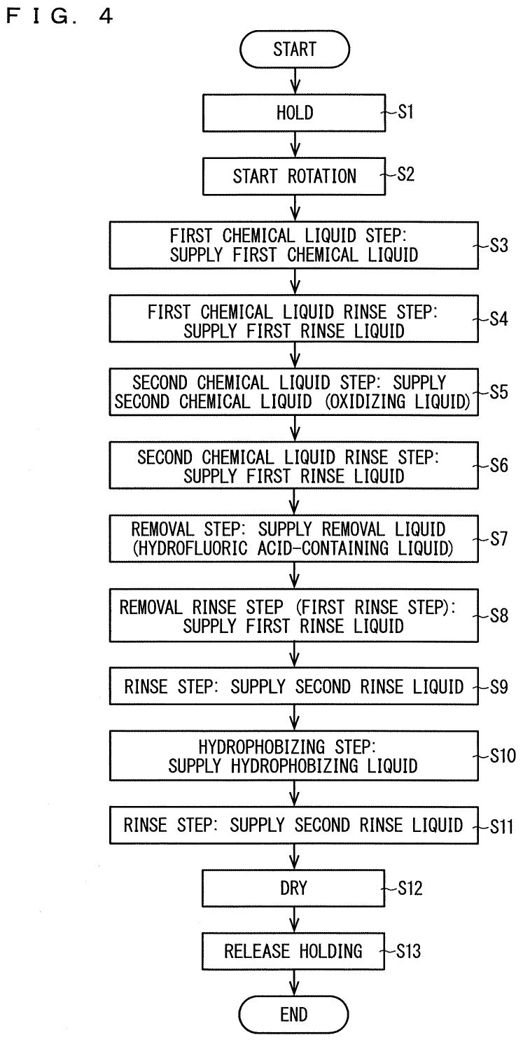

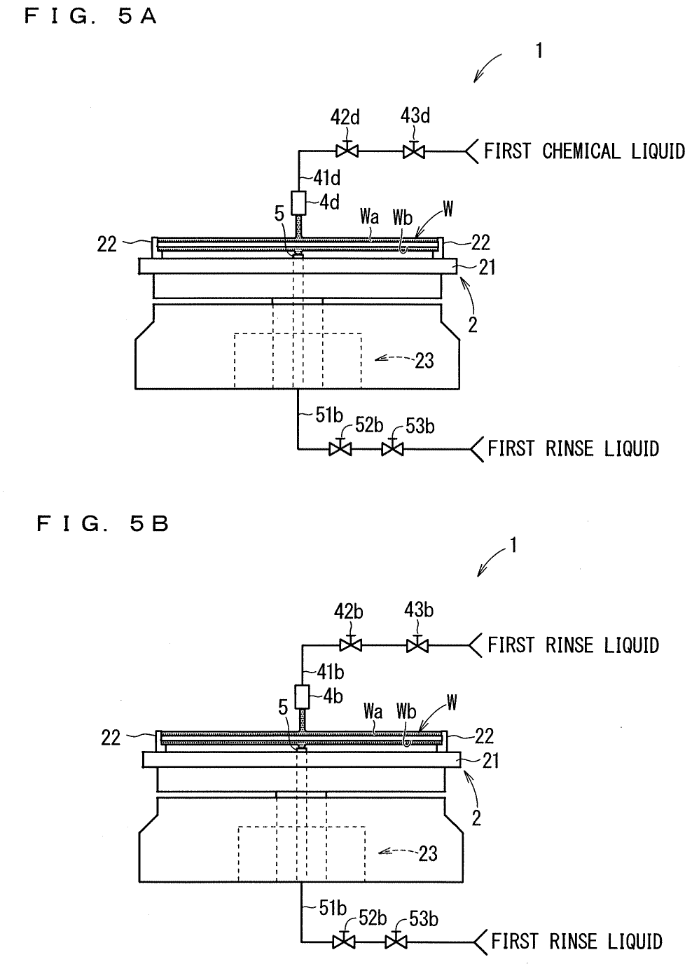

One example of operation of the processing unit 1 (i.e., a substrate processing method) will be described next. FIG. 4 is a flowchart showing one example of operation of the processing unit 1. The controller 90 causes the processing unit 1 to perform processing in Steps S1 to S13 according to processing procedures (a recipe) set in advance. FIGS. 5A to 8B are diagrams schematically showing examples of states of the processing unit 1 in respective steps.

First, the second transport 122 transports the substrate W to the processing unit 1. The substrate holder 2 holds the substrate W received from the second transport 122 (Step S1: HOLDING STEP). As one specific example, the substrate holder 2 displaces each of the plurality of chuck pins 22 from the releasing position to the holding position. The plurality of chuck pins 22 thus hold the substrate W. The substrate holder 2 continues to hold the substrate W until the end of processing on the substrate W.

Next, the substrate holder 2 starts rotation of the substrate W (Step S2: ROTATION START STEP). The substrate holder 2 may continue to rotate the substrate W until completion of processing on the substrate W.

Next, the processing unit 1 rotates the substrate W and supplies the first chemical liquid to the first main surface Wa of the substrate W (Step S3: FIRST CHEMICAL LIQUID STEP: SUPPLY FIRST CHEMICAL LIQUID). Specifically, the movement driver 45d first moves the first chemical liquid nozzle 4d to the processing position. The controller 90 opens the supply valve 42d. The first chemical liquid is thereby discharged from the first chemical liquid nozzle 4d toward the first main surface Wa of the substrate W being rotated as illustrated in FIG. 5A. The first chemical liquid sits on the central portion of the first main surface Wa of the substrate W, for example. The first chemical liquid sitting on the first main surface Wa of the substrate W is subjected to centrifugal force associated with rotation of the substrate W to flow radially outwards and splashes from the peripheral edge of the substrate W.

The controller 90 controls the flow rate regulation valve 43d and the substrate holder 2 at a flow rate (target value) and a rotation speed (target value) to the extent that the entire first main surface Wa of the substrate W is covered with a liquid film of the processing liquid (herein the first chemical liquid). In other words, the flow rate (target value) of the first chemical liquid and the rotation speed (target value) of the substrate W are set so that the entire first main surface Wa is covered with the liquid film of the first chemical liquid. This can reduce a possibility of adhesion of the particles to the first main surface Wa of the substrate W. The same applies to steps of discharging the other processing liquids described below.

The first chemical liquid acts on the first main surface Wa of the substrate W to perform processing depending on a type of the first chemical liquid on the first main surface Wa of the substrate W. When the first chemical liquid contains hydrofluoric acid, the native oxide film on the first main surface Wa of the substrate W is removed, for example. The native oxide film is a silicon oxide film, for example. When the native oxide film on the first main surface Wa of the substrate W is removed, a ground of the first main surface Wa of the substrate W is exposed. The ground is silicon, for example. The first main surface Wa of the substrate W after processing with the first chemical liquid is hydrophobic, for example. That is to say, the first main surface Wa of the substrate W from which the native oxide film has been removed has a greater contact angle than the first main surface Wa of the substrate W on which the native oxide film has been formed. A contact angle when water is dripped onto the first main surface Wa of the substrate W from which the native oxide film has been removed may be 90° or more, for example.

As illustrated in FIG. 5A, the processing unit 1 may supply the first rinse liquid to the second main surface Wb of the substrate W in parallel with supply of the first chemical liquid. Specifically, the controller 90 opens the supply valve 52b. The first rinse liquid is thereby discharged from the lower surface nozzle 5 toward the second main surface Wb of the substrate W being rotated. The first rinse liquid sits on a central portion of the second main surface Wb of the substrate W, for example. The first rinse liquid sitting on the second main surface Wb of the substrate W is subjected to centrifugal force associated with rotation of the substrate W to flow radially outwards and splashes from the peripheral edge of the substrate W. This can reduce a possibility of adhesion of the particles to the second main surface Wb of the substrate W.

When processing with the first chemical liquid on the substrate W is sufficiently performed, the controller 90 closes the supply valve 42d. As one specific example, the controller 90 determines whether an elapsed time since the start of discharge of the first chemical liquid is a predetermined first chemical liquid time or more. The first chemical liquid time is set in advance to a time to the extent that processing with the first chemical liquid is sufficiently performed. The elapsed time is measured by a timer circuit (not illustrated) belonging to the controller 90, for example. The controller 90 closes the supply valve 42d when the elapsed time is the first chemical liquid time or more. The movement driver 45d moves the first chemical liquid nozzle 4d to the standby position.

Next, the processing unit 1 rotates the substrate W and supplies the first rinse liquid to the first main surface Wa of the substrate W (Step S4: FIRST CHEMICAL LIQUID RINSE STEP: SUPPLY FIRST RINSE LIQUID). Specifically, the movement driver 45b first moves the first rinse nozzle 4b to the processing position. The controller 90 opens the supply valve 42b. The first rinse liquid is thereby discharged from the first rinse nozzle 4b toward the first main surface Wa of the substrate W being rotated as illustrated in FIG. 5B. The first rinse liquid sits on the central portion of the first main surface Wa of the substrate W, for example. The first rinse liquid sitting on the first main surface Wa of the substrate W is subjected to centrifugal force associated with rotation of the substrate W to flow radially outwards and splashes from the peripheral edge of the substrate W. In this case, the first rinse liquid washes away the processing liquid (herein the first chemical liquid) on the first main surface Wa of the substrate W radially outwards. The first chemical liquid as the processing liquid on the first main surface Wa of the substrate W is thereby substituted with the first rinse liquid.

As illustrated in FIG. 5B, the processing unit 1 may supply the first rinse liquid to the second main surface Wb of the substrate W in parallel with supply of the first rinse liquid to the first main surface Wa of the substrate W.

When the first chemical liquid is sufficiently substituted with the first rinse liquid, the controller 90 closes the supply valve 42b. As one specific example, the controller 90 measures an elapsed time since the start of discharge of the first rinse liquid and closes the supply valve 42b when the elapsed time is a predetermined first chemical liquid rinse time or more. The first chemical liquid rinse time is set in advance to a time to the extent that the first chemical liquid is sufficiently substituted with the first rinse liquid. After the supply valve 42b is closed, the movement driver 45b moves the first rinse nozzle 4b to the standby position.

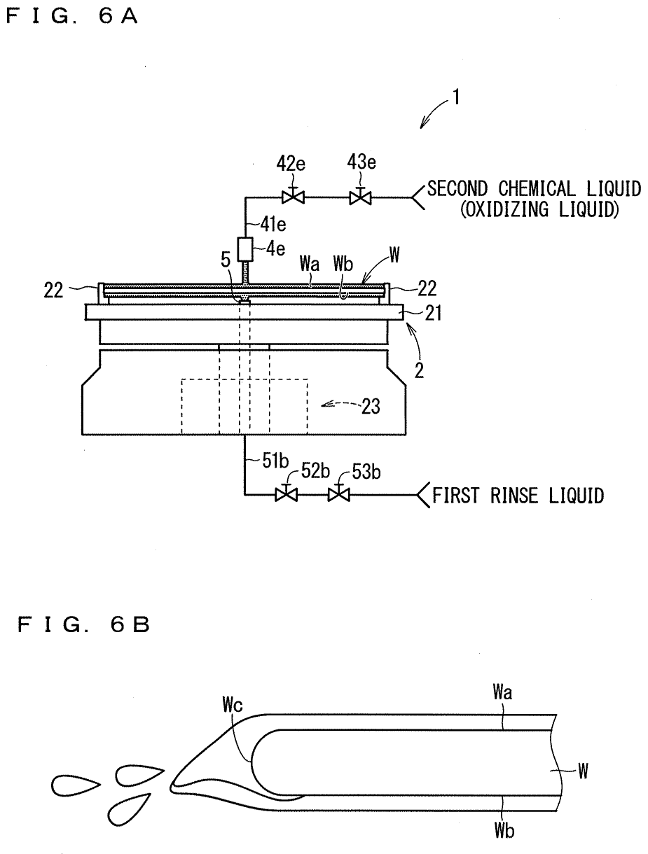

Next, the processing unit 1 rotates the substrate W and supplies the second chemical liquid to the first main surface Wa of the substrate W (Step S5: SECOND CHEMICAL LIQUID STEP: SUPPLY SECOND CHEMICAL LIQUID (OXIDIZING LIQUID)). Specifically, the movement driver 45e moves the second chemical liquid nozzle 4e to the processing position, and the controller 90 opens the supply valve 42e. The second chemical liquid is thereby discharged from the second chemical liquid nozzle 4e toward the first main surface Wa of the substrate W being rotated as illustrated in FIG. 6A. The second chemical liquid sits on the central portion of the first main surface Wa of the substrate W, for example. The second chemical liquid sitting on the first main surface Wa of the substrate W is subjected to centrifugal force associated with rotation of the substrate W to flow radially outwards and splashes from the peripheral edge of the substrate W. In this case, the second chemical liquid acts on the first main surface Wa of the substrate W to perform chemical liquid processing depending on a type of the second chemical liquid on the first main surface Wa of the substrate W. The second chemical liquid is a liquid having an oxidizing action on a surface of the substrate W. It can thus be said that the second chemical liquid is an oxidizing liquid. When the second chemical liquid is SC1, the processing unit 1 can remove the impurities, such as the particles, on the first main surface Wa of the substrate W.

The controller 90 controls the flow rate regulation valve 43e and the substrate holder 2 at a flow rate (target value) and a rotation speed (target value) to the extent that the entire first main surface Wa of the substrate W is covered with a liquid film of the processing liquid (herein the second chemical liquid). In other words, the flow rate (target value) of the second chemical liquid and the rotation speed (target value) of the substrate W are set so that the entire first main surface Wa is covered with the liquid film of the second chemical liquid. This can reduce the possibility of adhesion of the particles to the first main surface Wa of the substrate W. When the first main surface Wa of the substrate W is hydrophobic, the flow rate of the second chemical liquid is set to relatively high. The second chemical liquid is thus likely to wrap around an end surface Wc of the substrate W and can act on the end surface Wc and a peripheral edge portion of the second main surface Wb of the substrate W as illustrated in FIG. 6B. The end surface Wc and the peripheral edge portion of the second main surface Wb of the substrate W can thus also be oxidized.

As described above, due to processing with the second chemical liquid, an oxide film is formed one the first main surface Wa of the substrate W, and the oxide film can also be formed on the end surface Wc and the peripheral edge portion of the second main surface Wb of the substrate W. The oxide film is a silicon oxide film, for example. An OH group as a substituent group used for hydrophobizing, which will be described below, is present on a surface of the oxide film.

As illustrated in FIG. 6A, the processing unit 1 may supply the first rinse liquid to the second main surface Wb of the substrate W in parallel with supply of the second chemical liquid. Specifically, the controller 90 opens the supply valve 52b. The first rinse liquid is thereby discharged from the lower surface nozzle 5 toward the second main surface Wb of the substrate W being rotated. The first rinse liquid flows radially outwards on the second main surface Wb of the substrate W and splashes outwards from the peripheral edge of the substrate W. This can reduce the possibility of adhesion of the particles to the second main surface Wb of the substrate W. The first rinse liquid pushes the second chemical liquid wrapping around the end surface Wc of the substrate W radially outwards, so that a quantity of the wrapping-around second chemical liquid can be reduced.

When processing with the second chemical liquid on the substrate W is sufficiently performed, the controller 90 closes the supply valve 42e. As one specific example, the controller 90 closes the supply valve 42e when an elapsed time since the start of discharge of the second chemical liquid is a predetermined second chemical liquid time or more. The second chemical liquid time is set in advance to a time to the extent that processing with the second chemical liquid is sufficiently performed. The movement driver 45e moves the second chemical liquid nozzle 4e to the standby position.

Next, the processing unit 1 rotates the substrate W and supplies the first rinse liquid to the first main surface Wa of the substrate W (Step S6: SECOND CHEMICAL LIQUID RINSE STEP: SUPPLY FIRST RINSE LIQUID). The second chemical liquid as the processing liquid on the first main surface Wa of the substrate W is thereby substituted with the first rinse liquid. The processing unit 1 may supply the first rinse liquid to the second main surface Wb of the substrate W in parallel with supply of the first rinse liquid to the first main surface Wa of the substrate W.

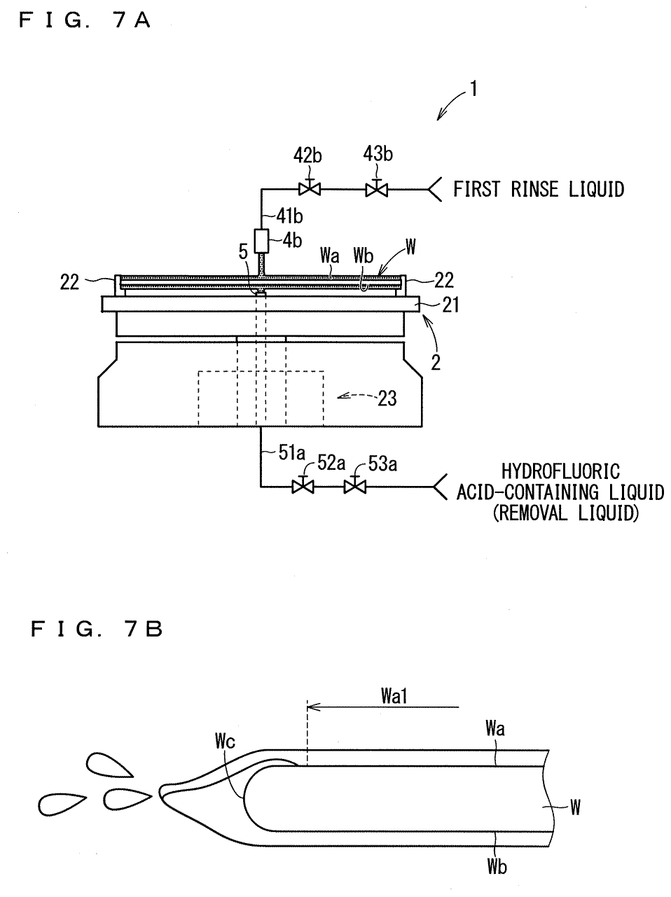

When the second chemical liquid is sufficiently substituted with the first rinse liquid, the processing unit 1 supplies the hydrofluoric acid-containing liquid to the second main surface Wb of the substrate W (Step S7: REMOVAL STEP: SUPPLY REMOVAL LIQUID (THE HYDROFLUORIC ACID-CONTAINING LIQUID)). As one specific example, the controller 90 closes the supply valve 52b and opens the supply valve 52a when an elapsed time since the start of discharge of the first rinse liquid is a predetermined second chemical liquid rinse time or more. The second chemical liquid rinse time is set in advance to a time to the extent that the second chemical liquid is sufficiently substituted with the first rinse liquid. When the supply valve 52a is opened, the hydrofluoric acid-containing liquid is discharged from the lower surface nozzle 5 toward the second main surface Wb of the substrate Was illustrated in FIG. 7A. The hydrofluoric acid-containing liquid sits on the central portion of the second main surface Wb of the substrate W, for example. The hydrofluoric acid-containing liquid sitting on the second main surface Wb of the substrate W is subjected to centrifugal force of the substrate W to flow radially outwards and splashes from the peripheral edge of the substrate W. The hydrofluoric acid-containing liquid acts on the second main surface Wb of the substrate W, so that at least portion of an oxide formed on the second main surface Wb of the substrate W is removed, for example. More specifically, almost all the oxide on the second main surface Wb of the substrate W is removed. It can be said that the hydrofluoric acid-containing liquid is a removal liquid that removes the oxide. While the substituent group used for hydrophobizing is present on the surface of the oxide, the hydrofluoric acid-containing liquid removes almost all the oxide, so that almost all the substituent group can be removed from the second main surface Wb of the substrate W.

As illustrated in FIG. 7A, the processing unit 1 may supply the first rinse liquid to the first main surface Wa of the substrate W in parallel with supply of the hydrofluoric acid-containing liquid to the second main surface Wb of the substrate W. This can reduce the possibility of adhesion of the particles to the first main surface Wa of the substrate W.

The processing unit 1 may control the flow rate regulation valve 43b, the flow rate regulation valve 53a, and the rotation driver 23 on a processing condition to the extent that the hydrofluoric acid-containing liquid wraps around the entire end surface Wc of the substrate Was illustrated in FIG. 7B. That is to say, a flow rate (target value) of the first rinse liquid, a flow rate (target value) of the hydrofluoric acid-containing liquid, and the rotation speed (target value) of the substrate W may be set so that the hydrofluoric acid-containing liquid wraps around the entire end surface Wc of the substrate W. The first main surface Wa of the substrate W has a device region Wal in which a device is formed and a peripheral edge region in which the device is not formed. The peripheral edge region is a region surrounding the device region Wal in plan view. The peripheral edge region has a width of 0.5 mm or more and 5 mm or less, for example. The processing unit 1 may control the flow rate regulation valve 43b, the flow rate regulation valve 53a, and the rotation driver 23 on a processing condition to the extent that the hydrofluoric acid-containing liquid wraps around the peripheral edge region without entering the device region Wal. Almost all the oxide on the end surface Wc of the substrate W can thereby be removed.

The controller 90 closes the supply valve 52a when the oxide on the peripheral edge portion of the second main surface Wb of the substrate W and further on the entire end surface Wc of the substrate W is sufficiently removed. As one specific example, the controller 90 closes the supply valve 52a when an elapsed time since the start of discharge of the hydrofluoric acid-containing liquid is a predetermined removal time or more. The removal time is set in advance to a time to the extent that the oxide on the peripheral edge portion of the second main surface Wb and the end surface Wc of the substrate W is sufficiently removed.

Next, the processing unit 1 supplies the first rinse liquid to the second main surface Wb of the substrate W (Step S8: REMOVAL RINSE STEP (FIRST RINSE STEP): SUPPLY FIRST RINSE LIQUID). Specifically, the controller 90 opens the supply valve 52b. The hydrofluoric acid-containing liquid as the processing liquid adhering to the second main surface Wb of the substrate W can thereby be substituted with the first rinse liquid. The processing unit 1 may supply the first rinse liquid to the first main surface Wa of the substrate W in parallel with supply of the first rinse liquid to the second main surface Wb of the substrate W (see FIG. 5B).

When the hydrofluoric acid-containing liquid is sufficiently substituted with the first rinse liquid, the controller 90 closes the supply valve 42b and the supply valve 52b. As one specific example, the controller 90 closes the supply valve 42b and the supply valve 52b when an elapsed time since the start of discharge of the first rinse liquid is a predetermined removal rinse time or more. The removal rinse time is set in advance to a time to the extent that the hydrofluoric acid-containing liquid is sufficiently substituted with the first rinse liquid. The movement driver 45b moves the first rinse nozzle 4b to the standby position.

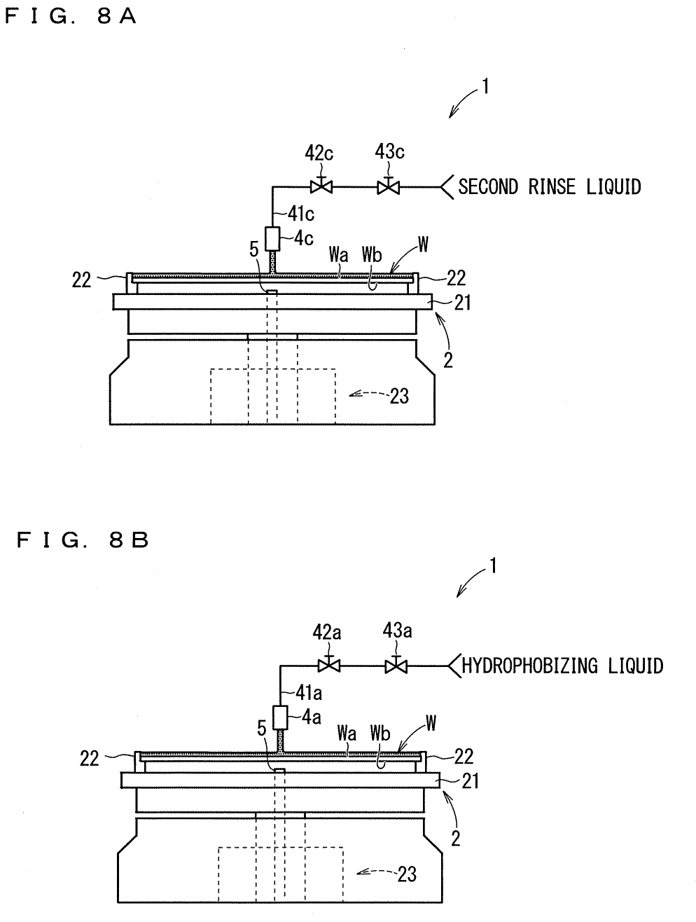

Next, the processing unit 1 rotates the substrate W and supplies the second rinse liquid to the first main surface Wa of the substrate W (Step S9: RINSE STEP: SUPPLY SECOND RINSE LIQUID). Specifically, the movement driver 45c moves the second rinse nozzle 4c to the processing position, and the controller 90 opens the supply valve 42c. The second rinse liquid is thereby discharged from the second rinse nozzle 4c toward the first main surface Wa of the substrate Was illustrated in FIG. 8A. The second rinse liquid sits on the central portion of the first main surface Wa of the substrate W, for example. The second rinse liquid sitting on the first main surface Wa of the substrate W is subjected to centrifugal force associated with rotation of the substrate W to flow radially outwards and splashes from the peripheral edge of the substrate W. The first rinse liquid as the processing liquid on the first main surface Wa of the substrate W can thereby be substituted with the second rinse liquid. In the example of FIG. 8A, the discharger 3 does not discharge the first rinse liquid to the second main surface Wb of the substrate W.

When the first rinse liquid is sufficiently substituted with the second rinse liquid, the controller 90 closes the supply valve 42c. As one specific example, the controller 90 closes the supply valve 42c when an elapsed time since the start of discharge of the second rinse liquid is a predetermined second A rinse time or more. The second A rinse time is set in advance to a time to the extent that the first rinse liquid is sufficiently substituted with the second rinse liquid. The movement driver 45c moves the second rinse nozzle 4c to the standby position.

Next, the processing unit 1 rotates the substrate W and supplies the hydrophobizing liquid to the first main surface Wa of the substrate W (Step S10: HYDROPHOBIZING STEP: SUPPLY HYDROPHOBIZING LIQUID). Specifically, the movement driver 45a moves the hydrophobizing nozzle 4a to the processing position, and the controller 90 opens the supply valve 42a. The hydrophobizing liquid is thereby discharged from the hydrophobizing nozzle 4a toward the first main surface Wa of the substrate W as illustrated in FIG. 8B. The hydrophobizing liquid sits on the central portion of the first main surface Wa of the substrate W, for example. The hydrophobizing liquid sitting on the first main surface Wa of the substrate W is subjected to centrifugal force associated with rotation of the substrate W to flow radially outwards and splashes from the peripheral edge of the substrate W. In this case, the hydrophobizing liquid acts on the first main surface Wa of the substrate W. Specifically, the hydrophobizing liquid contains the hydrophobic group (organic matter), and the substituent group on the substrate W is substituted with the hydrophobic group. For example, the hydrogen molecule of the hydroxy group present on the surface of the oxide on the substrate W is substituted with the trimethylsilyl group in a molecule of the hydrophobizing liquid. The first main surface Wa of the substrate W is thereby made hydrophobic.

While the hydrophobizing liquid wraps around the end surface Wc of the substrate W and can act on the peripheral edge portion of the second main surface Wb of the substrate W, almost all the oxide and the substituent group on the peripheral edge portion of the second main surface Wb of the substrate W are removed in Step S7. The peripheral edge portion of the second main surface Wb of the substrate W is thus rarely made hydrophobic even when the hydrophobic group flows to the peripheral edge portion of the second main surface Wb of the substrate W. That is to say, a phenomenon of substitution of the substituent group on the substrate W with the hydrophobic group (organic matter) in the molecule of the hydrophobizing liquid rarely occurs. The organic matter (hydrophobic group) is thus rarely contained in the peripheral edge portion of the second main surface Wb of the substrate W even when processing with the hydrophobizing liquid is performed.

When almost all the oxide and the substituent group on the end surface Wc of the substrate W are removed in Step S7, the end surface Wc of the substrate W is rarely made hydrophobic. That is to say, the organic matter (hydrophobic group) is rarely contained in the end surface Wc of the substrate W even when processing with the hydrophobizing liquid is performed.

As described above, the processing unit 1 can avoid hydrophobizing of the second main surface Wb and further the end surface Wc of the substrate W while making the first main surface Wa of the substrate W hydrophobic.

In the example of FIG. 8B, the discharger 3 does not discharge the first rinse liquid to the second main surface Wb of the substrate W.

When the first main surface Wa of the substrate W is sufficiently made hydrophobic, the controller 90 closes the supply valve 42a. As one specific example, the controller 90 closes the supply valve 42a when an elapsed time since the start of discharge of the hydrophobizing liquid is a predetermined hydrophobizing time or more. The hydrophobizing time is set in advance to a time to the extent that the first main surface Wa of the substrate W is sufficiently made hydrophobic. The movement driver 45a moves the hydrophobizing nozzle 4a to the standby position.

Next, the processing unit 1 rotates the substrate W and supplies the second rinse liquid to the first main surface Wa of the substrate W (Step S11: RINSE STEP: SUPPLY SECOND RINSE LIQUID). The hydrophobizing liquid as the processing liquid on the first main surface Wa of the substrate W can thereby be substituted with the second rinse liquid. As one example, the discharger 3 does not discharge the first rinse liquid to the second main surface Wb of the substrate W.

When the hydrophobizing liquid is sufficiently substituted with the second rinse liquid, the controller 90 closes the supply valve 42c. As one specific example, the controller 90 closes the supply valve 42c when an elapsed time since the start of discharge of the second rinse liquid is a predetermined second B rinse time or more. The second B rinse time is set in advance to a time to the extent that the hydrophobizing liquid is sufficiently substituted with the second rinse liquid. The movement driver 45c moves the second rinse nozzle 4c to the standby position.

In Step S11, the discharger 3 may supply a mixture of isopropyl alcohol and pure water (diluent IPA) to the first main surface Wa of the substrate W. In this case, the second rinse nozzle 4c is connected to a pure water supply source through an unillustrated branch tube, and a supply valve (not illustrated) and a flow rate regulation valve (not illustrated) are inserted along the branch tube.

Next, the processing unit 1 dries the substrate W (Step S12: DRYING STEP). For example, the substrate holder 2 increases the rotation speed of the substrate W (so-called spin drying). The substrate W is thereby dried.

Next, the substrate holder 2 releases holding of the substrate W (Step S13: HOLDING RELEASING STEP). For example, the substrate holder 2 moves each of the chuck pins 22 from the holding position to the releasing position. Holding of the substrate W is thereby released. Next, the second transport 122 transports the substrate W out of the processing unit 1.

As described above, the processing unit 1 can perform a series of processes on the substrate W. For example, the processing unit 1 can remove, with the second chemical liquid, the impurities, such as the particles, on the first main surface Wa of the substrate W from which the native oxide film has been removed (Step S5) while removing the native oxide film on the first main surface Wa of the substrate W with the first chemical liquid (Step S3). The oxide film (more specifically the substituent group) necessary for hydrophobizing can be formed on the first main surface Wa of the substrate W with the second chemical liquid.

The processing unit 1 supplies the hydrofluoric acid-containing liquid to the second main surface Wb of the substrate W (Step S7) before supplying the hydrophobizing liquid to the first main surface Wa of the substrate W (Step S10). Almost all the oxide and the substituent group on the peripheral edge portion of the second main surface Wb of the substrate W are thus removed at the time of supply of the hydrophobizing liquid. The peripheral edge portion of the second main surface Wb of the substrate W is thus rarely made hydrophobic even when the hydrophobizing liquid wraps around the peripheral edge portion of the second main surface Wb. In other words, the hydrophobic group (organic matter) rarely adheres to the peripheral edge portion of the second main surface Wb of the substrate W.

When the hydrofluoric acid-containing liquid wraps around the entire end surface Wc of the substrate W in Step S7, almost all the oxide and the substituent group can be removed from the entire end surface Wc of the substrate W. The end surface Wc of the second main surface Wb is thus rarely made hydrophobic even when the hydrophobizing liquid wraps around the end surface Wc of the substrate W in Step S10. In other words, the hydrophobic group (organic matter) rarely adheres to the end surface Wc of the substrate W.

On the other hand, the oxide film remains formed on the first main surface Wa (specifically the device region Wal) of the substrate W in Step S10. Hydrophobizing of the second main surface Wb and further the end surface Wc of the substrate W can thus be almost avoided while the first main surface Wa of the substrate W is made hydrophobic with the hydrophobizing liquid.

A contact angle of the second rinse liquid between patterns in the first main surface Wa is close to 90° during drying of the substrate W after hydrophobizing. This is because the first main surface Wa is a hydrophobic surface. A possibility of collapse of the pattern in the first main surface Wa of the substrate W during drying can thus be reduced.

According to this substrate processing method, the hydrophobic group (organic matter) rarely adheres to the second main surface Wb of the substrate W as described above. A hand of the second transport 122 is thus less likely to be contaminated with the organic matter when the hand is in contact with the second main surface Wb of the processed substrate W. A possibility of transfer of contamination with the organic matter to a plurality of substrates W via the hand can thus also be reduced.

In the above-mentioned specific example, the hydrophobic group (organic matter) rarely adheres to the end surface Wc of the substrate W. The carrier C is thus less likely to be contaminated with the organic matter upon contact of the end surface Wc of the substrate W with an inner surface of the carrier C when the substrate W is transported into the carrier C. A possibility of transfer of contamination with organic matter between a plurality of substrates W via the carrier C can thus also be reduced.

In the above-mentioned example, the first main surface Wa of the substrate W is oxidized with the second chemical liquid (oxidizing liquid) in Step S5. An oxide film having a controlled film thickness and the like is thus formed on the first main surface Wa of the substrate W. The oxide film suitable for hydrophobizing can thus be formed. After the oxide film is formed, the oxide on the second main surface Wb of the substrate W is removed with the hydrofluoric acid-containing liquid (Step S7). A possibility of adhesion of the organic matter to the second main surface Wb and further the end surface Wc of the substrate W can thus be reduced.

In the above-mentioned example, the first rinse liquid is supplied to the first main surface Wa of the substrate W in parallel with supply of the hydrofluoric acid-containing liquid (see FIG. 7A). The possibility of adhesion of the particles to the first main surface Wa of the substrate W can thus be reduced.

While the substrate holder 2 continues to rotate the substrate W in each step described below, rotation of the substrate W may be suspended as appropriate in each step.

### Second Embodiment

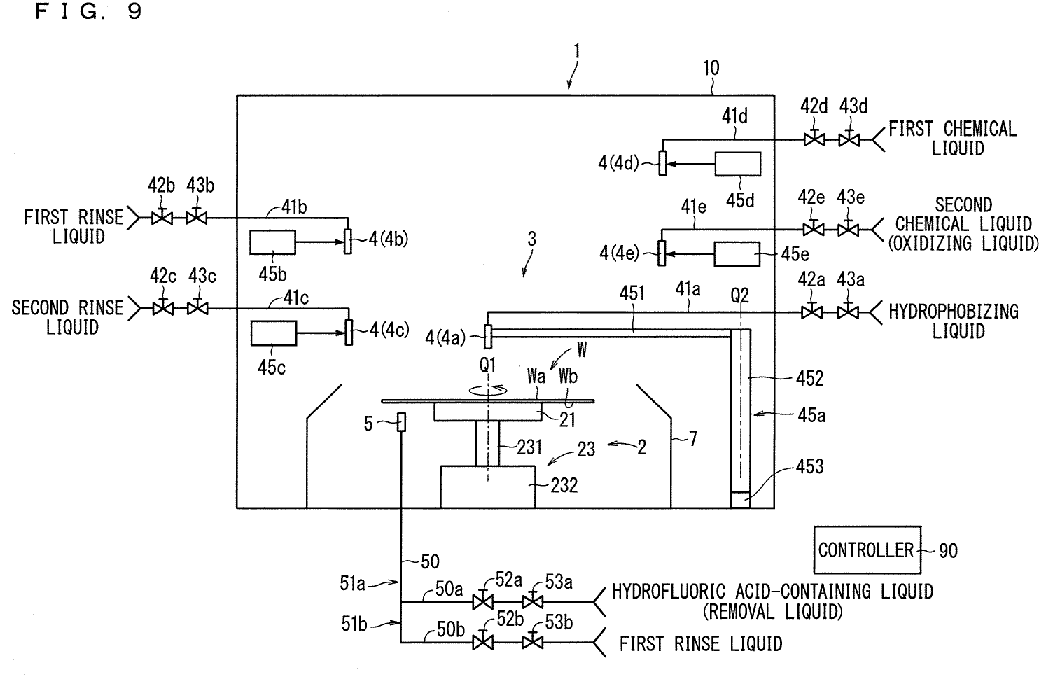

FIG. 9 is a diagram schematically showing one example of a configuration of a processing unit 1 according to a second embodiment. The processing unit 1 according to the second embodiment differs from the processing unit 1 according to the first embodiment in specific configuration of the substrate holder 2 and specific configuration of the discharger 3.

In the example of FIG. 9, the substrate holder 2 includes the spin base 21 and the rotation driver 23 and does not include the chuck pins 22. The spin base 21 is a suction stage. The spin base 21 has a planar shape, and the substrate W is mounted to an upper surface of the spin base 21. The upper surface of the spin base 21 has a plurality of discrete suction ports (not illustrated). The suction ports are each connected to a suction part (not illustrated) through an internal flow of the spin base 21. The suction part includes a pump, for example, and sucks gas from the suction ports. The second main surface Wb of the substrate W is thereby sucked to the upper surface of the spin base 21.

The spin base 21 is circular in plan view and has a smaller diameter than the substrate W. That is to say, the substrate W protrudes outward of the spin base 21 in plan view. A portion of the substrate W protruding outward of the spin base 21 is hereinafter referred to as a protrusion.

The lower surface nozzle 5 of the discharger 3 is provided at a position at which the lower surface nozzle 5 faces the protrusion of the substrate W held by the substrate holder 2 in the vertical direction. The lower surface nozzle 5 is horizontally adjacent to the substrate holder 2. The lower surface nozzle 5 discharges the hydrofluoric acid-containing liquid toward a peripheral edge portion of the substrate W. The lower surface nozzle 5 causes the hydrofluoric acid-containing liquid to sit on a sitting position that is the same as an innermost position of the second main surface Wb of the substrate W around which the second chemical liquid (oxidizing liquid) wraps or a sitting position radially inside the position. In other words, the lower surface nozzle 5 is provided at a position at which the hydrofluoric acid-containing liquid can sit at the sitting position.

One example of operation of the processing unit 1 according to the second embodiment is similar to that according to the first embodiment. However, the processing liquid (the hydrofluoric acid-containing liquid or the first rinse liquid) from the lower surface nozzle 5 is supplied to the peripheral edge portion of the second main surface Wb of the substrate W. The oxide on the peripheral edge portion of the second main surface Wb formed with the second chemical liquid can thereby also be removed with the hydrofluoric acid-containing liquid.

While the substrate processing apparatus 100 and the substrate processing method have been described in detail above, the foregoing description is in all aspects illustrative and not restrictive. Various modifications described above can be combined for application unless any contradiction occurs. It is understood that numerous unillustrated modifications can be devised without departing from the scope of the present disclosure.

The present disclosure includes aspects described below.

A first aspect is a substrate processing method including: a holding step of holding a substrate having a first main surface and a second main surface; a removal step of rotating the substrate and supplying a hydrofluoric acid-containing liquid to the second main surface of the substrate, the hydrofluoric acid-containing liquid containing hydrofluoric acid; a removal rinse step of rotating, after the removal step, the substrate and supplying a rinse liquid to the second main surface of the substrate; and a hydrophobizing step of rotating, after the removal rinse step, the substrate and supplying a hydrophobizing liquid to the first main surface of the substrate.

A second aspect is the substrate processing method according to the first aspect, further comprising: a chemical liquid step of rotating, before the removal step, the substrate and supplying a chemical liquid to the first main surface of the substrate to form an oxide on the first main surface of the substrate; and a chemical liquid rinse step of rotating, between the chemical liquid step and the removal step, the substrate and supplying a rinse liquid to the first main surface of the substrate, wherein in the removal step, an oxide is removed with the hydrofluoric acid-containing liquid, the oxide being formed by the chemical liquid wrapping around the second main surface from an end surface of the substrate and acting on the second main surface in the chemical liquid step.

A third aspect is the substrate processing method according to the second aspect, wherein in the chemical liquid step, the chemical liquid is supplied to the first main surface of the substrate while the substrate is rotated so that a liquid film of the chemical liquid covers the entire first main surface of the substrate being hydrophobic.

A fourth aspect is the substrate processing method according to any one of the first to the third aspects, wherein in the removal step, the hydrofluoric acid-containing liquid is supplied to the second main surface of the substrate while the substrate is rotated so that the hydrofluoric acid-containing liquid wraps around a peripheral edge portion of the first main surface from an end surface of the substrate.

A fifth aspect is the substrate processing method according to any one of the first to the fourth aspects, wherein in the removal step, a rinse liquid is supplied to the first main surface of the substrate in parallel with supply of the hydrofluoric acid-containing liquid to the second main surface of the substrate.

A sixth aspect is a substrate processing method including: a holding step of holding a substrate having a first main surface and a second main surface; a removal step of rotating the substrate and supplying a removal liquid to the second main surface of the substrate, the removal liquid removing an oxide; a removal rinse step of rotating, after the removal step, the substrate and supplying a rinse liquid to the second main surface of the substrate; and a hydrophobizing step of rotating, after the removal rinse step, the substrate and supplying a hydrophobizing liquid to the first main surface of the substrate.

According to the first to the sixth aspects, the hydrofluoric acid-containing liquid is supplied to the second main surface in the removal step, so that almost all the substituent group on the second main surface of the substrate can be removed, for example. The second main surface is thus rarely made hydrophobic even when the hydrophobizing liquid wraps around the second main surface from the end surface of the substrate in the hydrophobizing step. That is to say, a possibility of substitution of the substituent group on the substrate with the hydrophobic group (organic matter) in the molecule of the hydrophobizing liquid can be reduced. That is to say, a possibility of adhesion of the hydrophobic group (organic matter) to the second main surface of the substrate can be reduced.

According to the second aspect, the oxide film necessary for hydrophobizing can be formed on the first main surface of the substrate in the chemical liquid step. The first main surface of the substrate can thus properly be made hydrophobic in the hydrophobizing step.

According to the third aspect, the chemical liquid is supplied to cover the entire first main surface in the chemical liquid step, so that adhesion of the particles to the first main surface of the substrate can be reduced. The flow rate of the chemical liquid is high to cover the entire first main surface being hydrophobic with the chemical liquid, and, as a result, the chemical liquid is likely to wrap around the end surface of the substrate. The chemical liquid thus acts on the end surface and the peripheral edge portion of the second main surface of the substrate to form the oxide. Almost all the oxide on the second main surface can be removed in the removal step after the chemical liquid step. A possibility of hydrophobizing of the second main surface can thus be reduced even when the hydrophobizing liquid wraps around the end surface of the substrate in the hydrophobizing step.

According to the fourth aspect, almost all the oxide on the end surface of the substrate can be removed. A possibility of hydrophobizing of the end surface of the substrate in the hydrophobizing step can be reduced. That is to say, a possibility of adhesion of the organic matter to the end surface of the substrate can be reduced.

According to the fifth aspect, the possibility of adhesion of the particles to the first main surface of the substrate can be reduced.

While the disclosure has been shown and described in detail, the foregoing description is in all aspects illustrative and not restrictive. It is therefore understood that numerous modifications and variations can be devised.

What is claimed is:

1. A substrate processing method comprising:
holding a substrate having a first main surface and a second main surface;
rotating the substrate and supplying a hydrofluoric acid-containing liquid to the second main surface of the substrate, the hydrofluoric acid-containing liquid containing hydrofluoric acid;
after supplying the hydrofluoric acid-containing liquid to the second main surface of the substrate, rotating the substrate and supplying a rinse liquid to the second main surface of the substrate; and
after supplying the rinse liquid to the second main surface of the substrate, rotating the substrate and supplying a hydrophobizing liquid to the first main surface of the substrate.

2. The substrate processing method according to claim 1, further comprising:
before supplying the hydrofluoric acid-containing liquid to the second main surface of the substrate, rotating the substrate and supplying a chemical liquid to the first main surface of the substrate to form an oxide on the first main surface of the substrate; and
after forming the oxide on the first main surface of the substrate and before supplying the hydrofluoric acid-containing liquid to the second main surface of the substrate, rotating the substrate and supplying a rinse liquid to the first main surface of the substrate, wherein
in supplying the hydrofluoric acid-containing liquid to the second main surface of the substrate, an oxide is removed with the hydrofluoric acid-containing liquid, the oxide being formed by the chemical liquid wrapping around the second main surface from an end surface of the substrate and acting on the second main surface in forming the oxide on the first main surface of the substrate.

3. The substrate processing method according to claim 2, wherein
in forming the oxide on the first main surface of the substrate, the chemical liquid is supplied to the first main surface of the substrate while the substrate is rotated so that a liquid film of the chemical liquid covers the entire first main surface of the substrate being hydrophobic.

4. The substrate processing method according to claim 1, wherein
in supplying the hydrofluoric acid-containing liquid to the second main surface of the substrate, the hydrofluoric acid-containing liquid is supplied to the second main surface of the substrate while the substrate is rotated so that the hydrofluoric acid-containing liquid wraps around a peripheral edge portion of the first main surface from an end surface of the substrate.

5. The substrate processing method according to claim 1, wherein
in supplying the hydrofluoric acid-containing liquid to the second main surface of the substrate, a rinse liquid is supplied to the first main surface of the substrate in parallel with supply of the hydrofluoric acid-containing liquid to the second main surface of the substrate.

6. A substrate processing method comprising:
holding a substrate having a first main surface and a second main surface;
rotating the substrate and supplying a removal liquid to the second main surface of the substrate, the removal liquid removing an oxide;
after supplying the removal liquid to the second main surface of the substrate, rotating the substrate and supplying a rinse liquid to the second main surface of the substrate; and
after supplying the rinse liquid to the second main surface of the substrate, rotating the substrate and supplying a hydrophobizing liquid to the first main surface of the substrate.
